(19) United States
(12) Patent Application Publication
(10) Pub. No.: US 2014/0342652 A1
(43) Pub. Date: Nov. 20, 2014

(54) Air Cooling System and Electronic Device

(71) Applicant: Huawei Technologies Co., Ltd., Shenzhen (CN)

(72) Inventors: Yuan Dong, Shenzhen (CN); Mingxin Feng, Shenzhen (CN); Mingliang Hao, Shenzhen (CN)

(21) Appl. No.: 14/451,549

(22) Filed: Aug. 5, 2014

Related U.S. Application Data
(63) Continuation of application No. PCT/CN2013/072933, filed on Mar. 20, 2013.

(30) Foreign Application Priority Data
Aug. 24, 2012 (CN) 201210303917.X

(51) Int. Cl. H05K 7/20; F24F 7/007

(52) U.S. Cl. CPC H05K 7/20136; F24F 7/007
USPC 454/184; 454/338

(57) ABSTRACT

An air cooling system is provided. The air cooling system includes multiple air moving units and an air deflecting apparatus. The multiple air moving units are disposed upstream of air flowing through a heating component. The air deflecting apparatus is disposed between an air outlet of the multiple air moving units and the heating component. The air deflecting apparatus is configured to perform layering and deflecting for outgoing air of the multiple air moving units and divide the air into at least two layers. Air at each layer is supplied jointly by the multiple air moving units, and air directions of air in at least two adjacent layer spaces are different. According to the present disclosure, a heat dissipation impact resulting from a failure of a single air moving unit in the multiple air moving units can be effectively avoided.

### CROSS-REFERENCE TO RELATED APPLICATIONS

This application is a continuation of International Application No. PCT/CN2013/072933, filed on Mar. 20, 2013, which claims priority to Chinese Patent Application No. 201210303917.X, filed on Aug. 24, 2012, both of which are hereby incorporated by reference in their entireties.

### STATEMENT REGARDING FEDERALLY SPONSORED RESEARCH OR DEVELOPMENT

Not applicable.

### REFERENCE TO A MICROFICHE APPENDIX

Not applicable.

### TECHNICAL FIELD

The present disclosure relates to the field of electronics, and in particular, to an air cooling system and electronic device.

### BACKGROUND

An electronic device includes various electronic components. When the device is working, heat is generated in these electronic components, resulting in temperature rise in the electronic components. When temperature of the electronic components exceeds a certain value, damage or a function exception is caused due to overheat. Therefore, a proper cooling manner must be adopted to control working temperature of the electronic components within a proper range.

The following uses a common electronic device—a rack server as an example for description. The rack server generally uses an air cooling system for heat dissipation. Most air cooling systems use a fan for downdraught heat dissipation, that is, the fan is located in air upstream of electronic components and exhausts air to the electronic components. In the air cooling system, airflow passing through the electronic components is uneven due to uneven pressure distribution on an outlet side of the fan. Each fan provides heat dissipation for an electronic component that is directly located downstream of the fan. Once a single fan fails, a component downstream of the failed fan does not get sufficient cooling airflow, thereby encountering a heat dissipation problem. The cooling system of the rack server generally uses double-layer fans to avoid the heat dissipation problem in a case in which a single fan fails.

In comparison with single-layer fans, in the double-layer fans used in the cooling system, the number of fans required for air supply is almost doubled. As a result, the following main problems exist: a high cost of fan parts; an increased probability of overall fan failure; heavy maintenance workload; a large number of required spare parts; and high energy consumption and loud noise during fan operation.

### SUMMARY

To resolve the following problems in the prior art: problems of a high cost of fan parts, an increased probability of overall fan failure, and heavy maintenance workload, a problem of a large number of required spare parts, and a problem of high energy consumption and loud noise during fan operation, embodiments of the present disclosure provide an air cooling system and electronic device. The technical solutions are as follows:

According to one aspect, an air cooling system is provided for dissipating heat for a heating component. The air cooling system includes multiple air moving units and an air deflecting apparatus, where: the multiple air moving units are disposed upstream of air flowing through the heating component, and the multiple air moving units are configured to provide air required for dissipating heat for the heating component; and the air deflecting apparatus is disposed between an air outlet of the multiple air moving units and the heating component, and the air deflecting apparatus is configured to perform vertical layering and deflecting for outgoing air of the multiple air moving units and divide the air into at least two layers, where air at each layer is supplied jointly by the multiple air moving units, and air directions of air in at least two adjacent layer spaces are different.

Specifically, the air deflecting apparatus includes a horizontal plate and a vertical plate, where: the horizontal plate is disposed in a horizontal direction, and the horizontal plate is configured to divide the outgoing air of the multiple air moving units into at least two layers; and the vertical plate is vertically disposed in at least two layer spaces divided by the horizontal plate, and the vertical plate is configured to deflect air in a corresponding layer space.

Specifically, the air deflecting apparatus includes N horizontal plates and (N−1) vertical plates, where the N horizontal plates are triangular plates, the N horizontal plates are disposed in parallel in a vertical direction, all long edges of the triangular plates face air outlets of the multiple air moving units, the (N−1) vertical plates are separately disposed in layer spaces formed by the N horizontal plates, a vertical plate in each layer space is disposed vertically at one short edge of a horizontal plate in the layer space, vertical plates between at least two adjacent layers are disposed in a staggered manner at short edges of a horizontal plate shared by the vertical plates, and N≧2.

Specifically, the air deflecting apparatus includes multiple horizontal plates and multiple vertical plates, where the multiple horizontal plates are rectangular plates, the multiple horizontal plates are disposed in parallel in a vertical direction, all long edges of the rectangular plates face air outlets of the multiple air moving units, the multiple vertical plates are disposed vertically and regularly in layer spaces formed by the multiple horizontal plates, a vertical plate in each layer space is disposed in a same direction so that same air deflecting is formed in the layer space, and vertical plates in at least two adjacent layer spaces are disposed in a staggered manner so that staggered air deflecting is formed in the at least two adjacent layer spaces.

Specifically, the air deflecting apparatus is of an integrated structure.

Specifically, the air deflecting apparatus is of a split structure, the air deflecting apparatus includes multiple air deflecting units, the multiple air deflecting units correspond to the multiple air moving units in a one-to-one manner, the multiple air deflecting units are independent of each other, and the air deflecting units each deflect air for an air moving unit corresponding to the air deflecting units.

Each air deflecting unit divides, by using a horizontal plate, outgoing air of an air moving unit corresponding to each air deflecting unit into at least two layers, and outgoing air deflecting of adjacent layers is different, so that air directions of outgoing air of the adjacent layers are different.

Deflecting of all air deflecting units at a same layer in the air deflecting apparatus are the same, so that air directions of outgoing air of the same layer in the air deflecting apparatus are the same; and deflecting of air deflecting units at adjacent layers in the air deflecting apparatus is different, so that air directions of outgoing air of the adjacent layers in the air deflecting apparatus are different.

Further, the air cooling system includes multiple backflow prevention apparatuses. The multiple air moving units each have a backflow prevention apparatus. The backflow prevention apparatus is disposed at an air outlet of an air moving unit, so that when a single air moving unit fails, air is prevented, by using a corresponding backflow prevention apparatus, from flowing back to the single air moving unit.

Specifically, the air moving unit is a fan, and the multiple air moving units are connected in parallel.

Specifically, the fan is a speed-adjustable fan, and when a single fan fails, a same airflow volume can be reached by adjusting a rotational speed of a properly-functioning fan.

According to another aspect, an electronic device is provided and includes an enclosure and an electronic component, where the electronic component is disposed inside the enclosure, the electronic component is a heating component, the electronic device further includes the air cooling system, and the air cooling system is disposed inside the enclosure and performs, by using the air deflecting apparatus, layering and deflecting for outgoing air of the multiple air moving units, so that even heat dissipation airflow is formed at an outlet of the air deflecting apparatus, so as to perform heat dissipation for the electronic component.

Beneficial effects of the technical solutions provided by the embodiments of the present disclosure are as follows:

In the embodiments of the present disclosure, an air deflecting apparatus is disposed between an air outlet of multiple air moving units and a heating component, and layering and deflecting are performed by using the air deflecting apparatus for outgoing air of the multiple air moving units, so that even heat dissipation airflow is formed at an outlet of the air deflecting apparatus, and heat dissipation for the heating component in direct downstream of a faulty air moving unit can still be ensured even in a case in which a single air moving unit fails. Because the foregoing structure is used in the embodiments of the present disclosure, a heat dissipation requirement of the heating component when the multiple air moving units are normally working can be met, and a heat dissipation impact resulting from a failure of a single air moving unit in the multiple air moving units can also be effectively avoided. In comparison with conventional double-layer disposal of multiple air moving units, the number of air moving units can be reduced, thereby reducing costs of the air moving units; an overall failure probability of the multiple air moving units can be lowered, thereby reducing maintenance workload and the number of spare parts; and operating energy consumption of the multiple air moving units and noise can be reduced. Therefore, an electronic device disposed with the cooling system has advantages of a good heat dissipation effect and stable operating.

### BRIEF DESCRIPTION OF THE DRAWINGS

To describe the technical solutions in the embodiments of the present disclosure more clearly, the following briefly introduces the accompanying drawings required for describing the embodiments of the present disclosure. The accompanying drawings in the following description show merely some embodiments of the present disclosure, and a person of ordinary skill in the art may still derive other drawings from these accompanying drawings without creative efforts.

FIG. 1 is a schematic structural diagram of a cooling system according to an embodiment of the present disclosure;

FIG. 2 is a schematic structural diagram of an air deflecting apparatus according to an embodiment of the present disclosure;

FIG. 2A is a schematic structural diagram of an air deflecting apparatus according to another embodiment of the present disclosure;

FIG. 3 is a schematic structural diagram of an air deflecting apparatus according to still another embodiment of the present disclosure;

FIG. 3A is a schematic structural diagram of an air deflecting apparatus according to yet another embodiment of the present disclosure;

FIG. 4 is a schematic structural diagram of a cooling system according to yet another embodiment of the present disclosure;

FIG. 5 is a schematic structural diagram of an air moving unit and an air deflecting unit according to yet another embodiment of the present disclosure;

FIG. 6 is a schematic structural diagram of a backflow prevention apparatus according to an embodiment of the present disclosure; and

FIG. 7 is a schematic structural diagram of an electronic device according to yet another embodiment of the present disclosure.

Symbols in the figures indicate the following meanings:

1 Air cooling system, 10 Multiple air moving units, 10A Air outlet of multiple air moving units, 10B Air moving unit, 11 First air moving unit, 12 Second air moving unit, 13 Third air moving unit, 14 Fourth air moving unit, 15 Fifth air moving unit, 20 Air deflecting apparatus, 20A Air deflecting unit, 21 Horizontal plate, 21A First horizontal plate, 21A1 Long edge of the first horizontal plate; 21A2 First short edge of the first horizontal plate, 21A3 Second short edge of the first horizontal plate, 21B Second horizontal plate, 21B2 First short edge of the second horizontal plate, 21B3 Second short edge of the second horizontal plate, 21C Third horizontal plate, 21D Fourth horizontal plate, 22 Vertical plate, 22A First vertical plate, 22B Second vertical plate, 22C Third vertical plate, 22D Fourth vertical plate, 30 Backflow prevention apparatus, 31 Rotatable blade, 2 Heating component, 3 Enclosure, and 100 Electronic device.

### DETAILED DESCRIPTION

To make the objectives, technical solutions, and advantages of the present disclosure clearer, the following further describes the embodiments of the present disclosure in detail with reference to the accompanying drawings.

### Embodiment 1

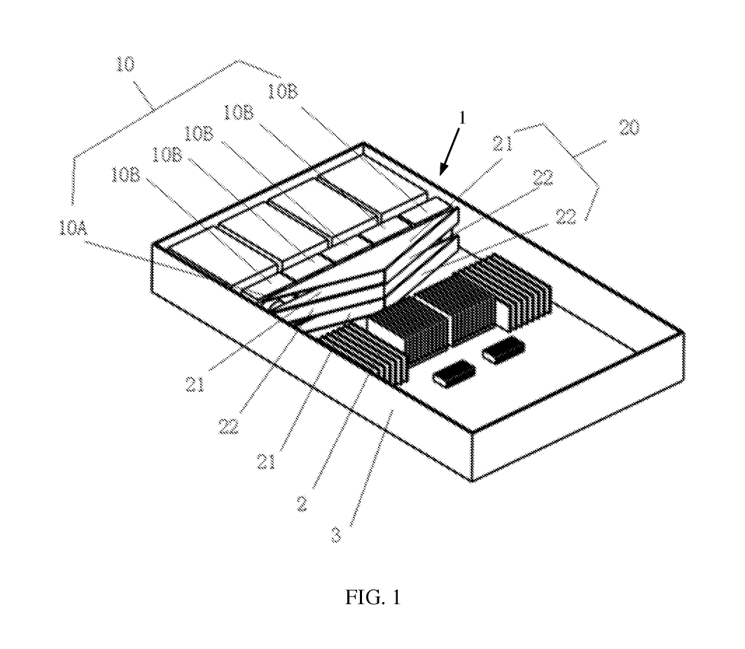

As shown in FIG. 1, an embodiment of the present disclosure provides an air cooling system 1. The air cooling system 1 performs heat dissipation for a heating component 2. The air cooling system 1 includes multiple air moving units 10 and an air deflecting apparatus 20.

The multiple air moving units 10 are disposed upstream of air flowing through the heating component 2. The multiple air moving units 10 are configured to provide air required for dissipating heat for the heating component 2.

The air deflecting apparatus 20 is disposed between an air outlet 10A of the multiple air moving units and the heating component 2. The air deflecting apparatus 20 is configured to perform vertical layering and deflecting for outgoing air of the multiple air moving units 10 and divide the air into at least two layers, where air at each layer is supplied jointly by the multiple air moving units 10, and air directions of air in at least two adjacent layer spaces are different.

The upstream specifically refers to a start point of air. The vertical layering is to divide a vertical plane into multiple layers. Specifically, the layering is implemented by using multiple horizontal planes. After the layering, the horizontal planes are parallel to each other, and spacing is provided between adjacent horizontal planes.

A working principle of the embodiment of the present disclosure is as follows: as shown in FIG. 1, when outgoing air of the multiple air moving units 10 is exhausted to the air deflecting apparatus 20, the air is partitioned into multiple layers by the air deflecting apparatus 20. At each layer, outgoing air of the multiple air moving units 10 that is not blocked by the air deflecting apparatus 20 flows to downstream according to an original airflow path, and specific deflecting is performed, according to a direction of the air deflecting apparatus 20, for outgoing air of the multiple air moving units 10 that is blocked by the air deflecting apparatus 20. Because the air deflecting apparatus 20 is divided into multiple layers, directions of flow deflecting of the air deflecting apparatus 20 of at least two adjacent layers are different.

In a case in which the multiple air moving units 10 are normally working, airflow at the outlet of the air deflecting apparatus 20 is mutually mixed and evenly distributed. This does not affect an original heat dissipation effect.

In a case in which a single air moving unit 10B is faulty, because the air deflecting apparatus 20 has performed the foregoing layering and deflecting for the airflow so that original airflow distribution in a case in which the multiple air moving units 10 are used for heat dissipation changes, cooling airflow from other air moving units 10B still exists at the direct downstream of the failed air moving unit 10B, thereby resolving a difficult problem of a failure of a single air moving unit 10B and lowering a risk of heat dissipation.

Because the foregoing structure is used in the embodiment of the present disclosure uses, a heat dissipation requirement of the heating component 2 when the multiple air moving units 10 are normally working can be met, and a heat dissipation impact resulting from a failure of a single air moving unit 10B in the multiple air moving units 10 can also be effectively avoided. Compared with conventional double-layer disposal of multiple air moving units 10, single-layer disposal of multiple air moving units 10B can be used, so that the number of air moving units 10B can be reduced, thereby reducing costs of the air moving units 10B; an overall failure probability of the multiple air moving units 10 can be lowered, thereby reducing maintenance and the number of spare parts; and operating energy consumption of the multiple air moving units 10 and noise can be reduced.

In addition, the air deflecting apparatus 20 has a simple structure and has advantages of easy processing and a low cost.

In addition, the air deflecting apparatus 20 has low resistance that hardly affects an operating point of the air moving units 10B and an air volume of the cooling system.

Specifically, as shown in FIG. 1, the air deflecting apparatus 20 includes a horizontal plate 21 and a vertical plate 22, where: the horizontal plate 21 is disposed in a horizontal direction, and the horizontal plate 21 is configured to divide the outgoing air of the multiple air moving units 10 into at least two layers; and the vertical plate 22 is vertically disposed in at least two layer spaces divided by the horizontal plate 21, and the vertical plate 22 is configured to deflect air in a corresponding layer space.

The layer space refers to a space formed by two horizontal plates.

Specifically, as shown in FIG. 1, in this embodiment, the air deflecting apparatus 20 includes at least one horizontal plate 21 and at least two vertical plates 22, where: the at least one horizontal plate 21 is disposed in a horizontal direction, and the at least one horizontal plate 21 is configured to divide the outgoing air of the multiple air moving units 10 into at least two layers; and the at least two vertical plates 22 are separately and vertically disposed in the at least two layer spaces divided by the at least one horizontal plate 21, and the at least two vertical plates 22 are configured to deflect air in a layer space.

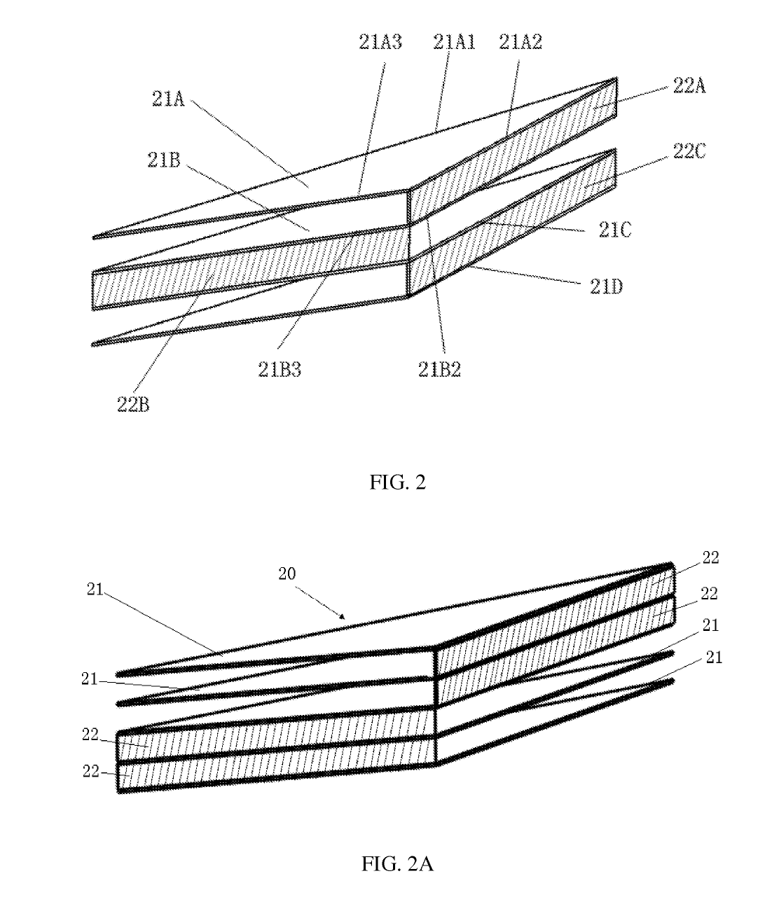

More specifically, as shown in FIG. 2, in this embodiment, the air deflecting apparatus 20 includes N horizontal plates 21 and (N−1) vertical plates 22, where the N horizontal plates 21 are triangular plates, the N horizontal plates 21 are disposed in parallel in a vertical direction, and all long edges of the triangular plates face air outlets 10A of the multiple air moving units. The (N−1) vertical plates 22 are separately disposed in layer spaces formed by the N horizontal plates, a vertical plate 22 in each layer space is disposed vertically at one short edge of a horizontal plate 21 in the layer space, vertical plates 22 between at least two adjacent layers are disposed in a staggered manner at short edges of a horizontal plate 21 shared by the vertical plates 22, and N≧2.

The vertical direction is a relative concept. In this embodiment, the vertical direction refers to a direction perpendicular to a horizontal plane.

The horizontal plate 21 in this embodiment is a triangular plate, so that after the air deflecting apparatus 20 is placed in a chassis, two spaces can be reserved at two short edges of the triangular plate. A first horizontal plate 21A is used as an example for description. Two spaces can be reserved at two short edges 21A2 and 21A3 of the first horizontal plate 21A. In a case in which the air deflecting apparatus 20 is not disassembled, a component in the two spaces can be repaired. This has an advantage of convenient repair.

More specifically, as shown in FIG. 2, in this embodiment, N is four, and the air deflecting apparatus 20 includes four horizontal plates 21 and three vertical plates 22. The four horizontal plates 21 are a first horizontal plate 21A, a second horizontal plate 21B, a third horizontal plate 21C, and a fourth horizontal plate 21D. The three vertical plates 22 are a first vertical plate 22A, a second vertical plate 22B, and a third vertical plate 22C.

The first horizontal plate 21A, the second horizontal plate 21B, the third horizontal plate 21C, and the fourth horizontal plate 21D are triangular plates. The first horizontal plate 21A, the second horizontal plate 21B, the third horizontal plate 21C, and the fourth horizontal plate 21D are disposed in parallel in a vertical direction, and all long edges of the triangular plates face air outlets 10A of the multiple air moving units. The first horizontal plate 21A is used as an example for description. The first horizontal plate 21A includes a long edge 21A1 of the first horizontal plate, a first short edge 21A2 of the first horizontal plate, and a second short edge 21A3 of the first horizontal plate, where the long edge 21A1 of the first horizontal plate faces air outlets 10A of the multiple air moving units 10.

The three vertical plates 22 are separately disposed in layer spaces formed by the four horizontal plates 21. The four horizontal plates form three layers. Specifically, the first vertical plate 22A is disposed in a first layer space formed by the first horizontal plate 21A and the second horizontal plate 21B, the second vertical plate 22B is disposed in a second layer space formed by the second horizontal plate 21B and the third horizontal plate 21C, and the third vertical plate 22C is disposed in a third layer space formed by the third horizontal plate 21C and the fourth horizontal plate 21D. A vertical plate 22 in each layer space is disposed vertically at one short edge of a horizontal plate in the layer space. The first layer space formed by the first horizontal plate 21A and the second horizontal plate 21B is used as an example for description. The first vertical plate 22A in the first layer space is disposed vertically at the first short edge 21A2 of the first horizontal plate. Vertical plates 22 between two adjacent layers are disposed in a staggered manner at short edges of a horizontal plate shared by the vertical plates 22. The first layer space and the second layer space are used as an example for description. The first vertical plate 22A and the second vertical plate 22B are disposed in a staggered manner at short edges of the second horizontal plate 21B, the first vertical plate 22A is disposed at the first short edge 21B2 of the second horizontal plate 21B (that is, disposed on the right in FIG. 2), and the second vertical plate 22B is disposed at the second short edge 21B3 of the second horizontal plate 21B (that is, disposed on the left in FIG. 2). Staggered disposal indicates that disposal directions of the vertical plates 22 are inconsistent, so that air is exhausted from a left side of the first layer space, air is exhausted from a right side of the second layer space, and air is exhausted from a left side of the third layer space. That is, in this embodiment, air directions of air in layer spaces of any adjacent layers are different.

As shown in FIG. 2A, a difference between this embodiment and the embodiment shown in FIG. 2 lies in that: N is five, the air deflecting apparatus 20 includes five horizontal plates 21 and four vertical plates 22, and the five horizontal plates 21 form four layer spaces that are a first layer space to a fourth layer space from top to bottom, where a vertical plate 22 in the first layer space and a vertical plate 22 in the second layer space are disposed vertically at a right short edge of a horizontal plate 21 in the layer space, a vertical plate 22 in the third layer space and a vertical plate 22 in the fourth layer space are disposed vertically at a left short edge of a horizontal plate 21 in the layer space, and the vertical plate 22 in the second layer space and the vertical plate 22 in the third layer space are disposed in a staggered manner. In this embodiment, in two adjacent layers, only air directions of air in layer spaces of a second layer and a third layer are different.

Certainly, a person of ordinary skill in the art may understand that a vertical plate 22 in each layer space is disposed vertically at a short edge of a horizontal plate 21 in the layer space, vertical plates 22 between at least two adjacent layers are disposed in a staggered manner at short edges of a horizontal plate 21 shared by the vertical plates 22, and air directions of air in at least two adjacent layer spaces are different.

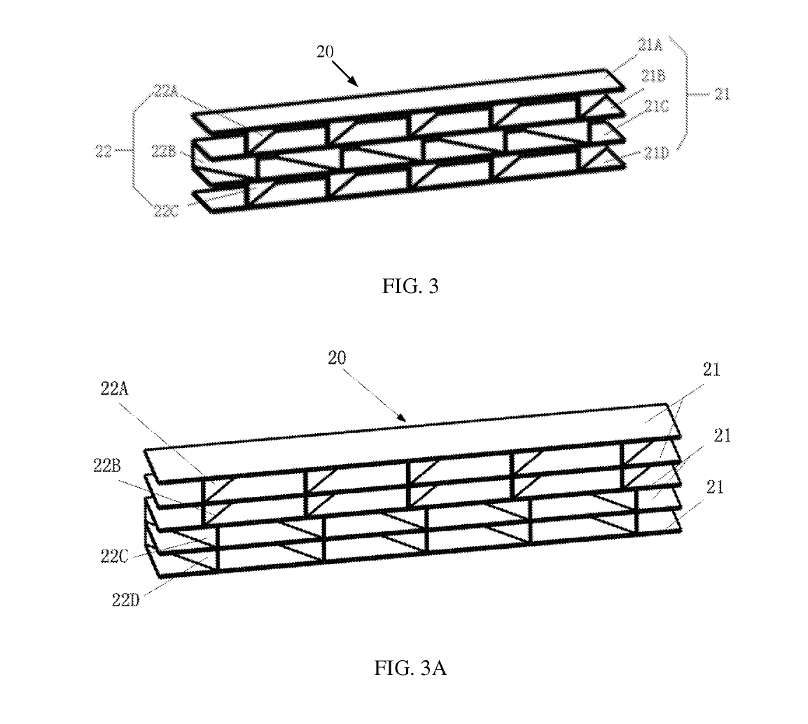

Specifically, as shown in FIG. 3, in this embodiment, the air deflecting apparatus 20 includes multiple horizontal plates 21 and multiple vertical plates 22. The multiple horizontal plates 21 are rectangular plates, the multiple horizontal plates 21 are disposed in parallel in a vertical direction, all long edges of the rectangular plates face air outlets 10A of the multiple air moving units, the multiple vertical plates 22 are disposed vertically and regularly in layer spaces formed by the multiple horizontal plates 21, a vertical plate 22 in each layer space is disposed in a same direction so that same air deflecting is formed in the layer space, and vertical plates 22 in at least two adjacent layer spaces are disposed in a staggered manner so that staggered air deflecting is formed in the at least two adjacent layer spaces. In this embodiment, the foregoing structure is used and has advantages of a simple structure and easy processing and manufacturing.

More specifically, as shown in FIG. 3, in this embodiment, the air deflecting apparatus 20 includes four horizontal plates 21 and fifteen vertical plates 22.

The four horizontal plates 21 are a first horizontal plate 21A, a second horizontal plate 21B, a third horizontal plate 21C, and a fourth horizontal plate 21D. The first horizontal plate 21A, the second horizontal plate 21B, the third horizontal plate 21C, and the fourth horizontal plate 21D are all rectangular plates, the first horizontal plate 21A, the second horizontal plate 21B, the third horizontal plate 21C, and the fourth horizontal plate 21D are disposed in parallel in a vertical direction, and all long edges of the first horizontal plate 21A, the second horizontal plate 21B, the third horizontal plate 21C, and the fourth horizontal plate 21D face air outlets 10A of the multiple air moving units.

The fifteen vertical plates 22 are disposed vertically and regularly in three layer spaces formed by the four horizontal plates 21. The fifteen vertical plates 22 are divided into three groups, that is, a first group of vertical plates formed by first vertical plates 22A, a second group of vertical plates formed by second vertical plates 22B, and a third group of vertical plates formed by third vertical plates 22C. Each group of vertical plates 22 is disposed in a layer space formed by horizontal plates 21, the first group of vertical plates 22A is disposed in a first layer space formed by the first horizontal plate 21A and the second horizontal plate 21B, the second group of vertical plates 22B is disposed in a second layer space formed by the second horizontal plate 21B and the third horizontal plate 21C, and the third group of vertical plates 22C is disposed in a third layer space formed by the third horizontal plate 21C and the fourth horizontal plate 21D.

A vertical plate 22 in each layer space is disposed in a same direction, so that same air deflecting is formed in the layer space. In this embodiment, the first layer space formed by the first horizontal plate 21A and the second horizontal plate 21B is used as an example for description. Five first vertical plates 22A in the first layer space are vertically disposed between the first horizontal plate 21A and the second horizontal plate 21B, and the five first vertical plates 22A are all disposed towards the left so that left air deflecting is formed in the first layer space.

Vertical plates in two adjacent layer spaces are disposed in a staggered manner, so that staggered air deflecting is formed in the adjacent layer spaces. That is, in this embodiment, air directions of air in layer spaces of any adjacent layers are different. In this embodiment, the first layer space and the second layer space are used as an example for description. Five second vertical plates 22B in the second layer space are vertically disposed between the second horizontal plate 21B and the third horizontal plate 21C, and the five second vertical plates 22B are all disposed towards the right so that right air deflecting is formed in the second layer space, that is, the first vertical plates 22A and the second vertical plates 22B in the first layer space and the second layer space are disposed in a staggered manner, so that left air deflecting and right air deflecting are formed in the first layer space and the second layer space respectively.

Most preferably, vertical plates in adjacent layer spaces are disposed in opposite directions. This structure can avoid existence of a heat dissipation dead angle.

Certainly, a person of ordinary skill in the art may understand that the number of horizontal plates 21 and the number of vertical plates 22 are not limited thereto and may be determined according to an actual heat dissipation requirement in specific implementation.

As shown in FIG. 3A, a difference between this embodiment and the embodiment shown in FIG. 3 lies in that: the air deflecting apparatus 20 includes five horizontal plates 21 and twenty vertical plates 22 (reference may be made to FIG. 3), the five horizontal plates 21 form four layer spaces that are a first layer space to a fourth layer space from top to bottom, the twenty vertical plates 22 (reference may be made to FIG. 3) are divided into four groups, and each group includes five vertical plates 22 (reference may be made to FIG. 3), that is, the four layer spaces correspond to four groups of vertical plates. The first vertical plate 22A in the first layer space and the second vertical plate 22B in the second layer space are disposed towards the left, the third vertical plate 22C in the third layer space and the fourth vertical plate 22D in the fourth layer place are disposed towards the right, and the second vertical plate 22B in the second layer space and the third vertical plate 22C in the third layer space are disposed in a staggered manner. That is, in this embodiment, at two adjacent layers, only air directions of air in layer spaces of a second layer and a third layer are different.

Certainly, a person of ordinary skill in the art may understand that a vertical plate 22 in each layer space are disposed in a same direction so that same air deflecting is formed in the layer space, and vertical plates 22 in at least two adjacent layer spaces are disposed in a staggered manner so that staggered air deflecting is formed in the at least two adjacent layer spaces.

Specifically, as shown in FIG. 3, in this embodiment, the air deflecting apparatus 20 is of an integrated structure.

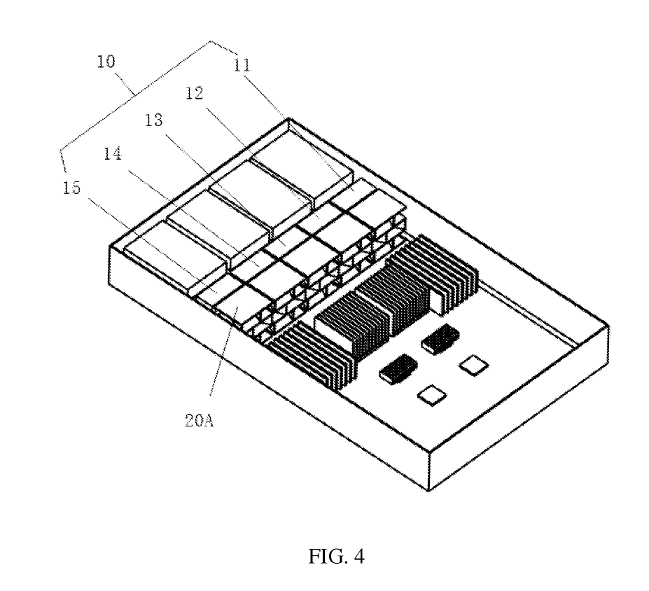

Specifically, as shown in FIG. 4, in this embodiment, the air deflecting apparatus 20 is of a split structure. The air deflecting apparatus 20 includes multiple air deflecting units 20A, the multiple air deflecting units 20A correspond to multiple air moving units 10B in a one-to-one manner. The multiple air deflecting units 20A are independent of each other. The air deflecting units 20A each deflect air for an air moving unit 10B corresponding to the air deflecting units 20A. Each air deflecting unit 20A divides, by using a horizontal plate 21, outgoing air of an air moving unit 10B corresponding to each air deflecting unit 20A into at least two layers. Outgoing air deflecting of adjacent layers is different, so that air directions of outgoing air of the adjacent layers are different. Deflecting of all air deflecting units 20A at a same layer in the air deflecting apparatus 20 are the same, so that air directions of outgoing air of the same layer in the air deflecting apparatus 20 are the same. Deflecting of air deflecting units 20A at adjacent layers in the air deflecting apparatus 20 is different, so that air directions of outgoing air of the adjacent layers in the air deflecting apparatus 20 are different.

In this embodiment, the split structure is used, which is easy for processing, storage, and repair.

Certainly, a person of ordinary skill in the art may understand that the air deflecting apparatus 20 in this embodiment may also be of the integrated structure.

More specifically, as shown in FIG. 4, in this embodiment, the multiple air moving units 10 include five air moving units 10B, that is, a first air moving unit 11, a second air moving unit 12, a third air moving unit 13, a fourth air moving unit 14, and a fifth air moving unit 15. The five air moving units 11 to 15 are disposed in a single row, and correspondingly, the air deflecting apparatus 20 also includes five air deflecting units 20A.

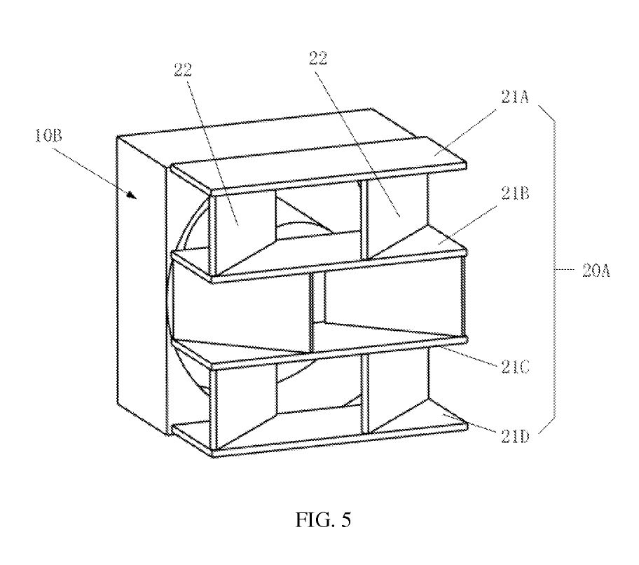

As shown in FIG. 5, each air deflecting unit 20A and an air moving unit 10B corresponding to the air deflecting unit 20A form one cooling unit. Each air deflecting unit 20A divides, by using the first horizontal plate 21A to the fourth horizontal plate 21D, outgoing air of a corresponding air moving unit 10B into three layers. Two vertical plates 22 in a layer space are configured to deflect air for the layer space. Air deflecting of adjacent layers is different, that is, outgoing air deflecting of a first layer is different from outgoing air deflecting of a second layer, and the outgoing air deflecting of the second layer is different from outgoing air deflecting of a third layer, so that air directions of outgoing air of the adjacent layers are different. In this embodiment, air is exhausted from a left side at the first layer, air is exhausted from a right side at the second layer, and air is exhausted from a left side at the third layer.

Five air deflecting units 20A shown in FIG. 5 are disposed in one row, that is, the air deflecting apparatus 20 shown in FIG. 4. As shown in FIG. 4, deflecting of all air deflecting units 20A at a same layer in the air deflecting apparatus 20 is the same. Air exhausted from a left side of five air deflecting units 20A at a first layer, air is exhausted from a right side of five air deflecting units 20A at a second layer, and air is exhausted from a left side of five air deflecting units 20A at a third layer, so that air directions of outgoing air of a same layer in the air deflecting apparatus 20 are the same. Deflecting of air deflecting units 20A at adjacent layers in the air deflecting apparatus 20 is different, so that air directions of outgoing air of the adjacent layers in the air deflecting apparatus 20 are different.

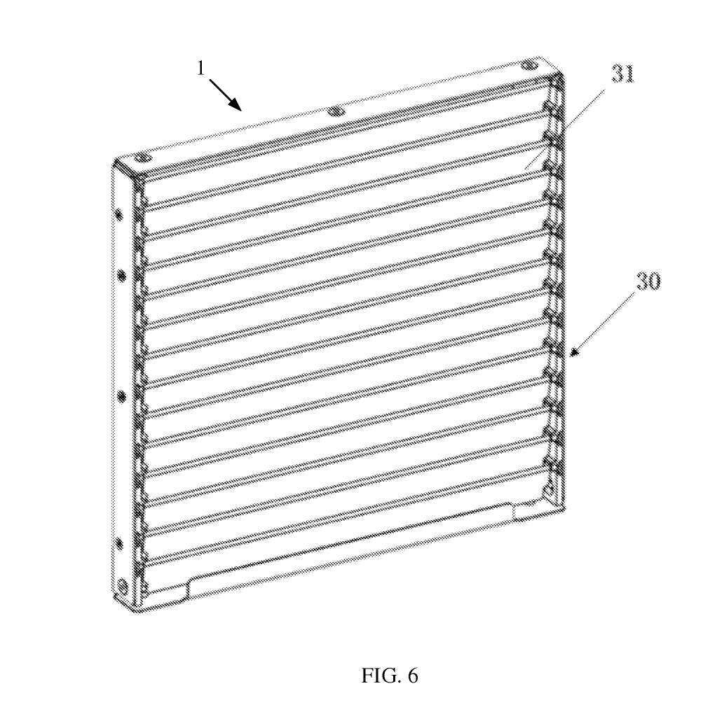

Further, as shown in FIG. 6, an air cooling system 1 (reference may be made to FIG. 1) includes multiple backflow prevention apparatuses 30. Multiple air moving units 10B (reference may be made to FIG. 1) each have a backflow prevention apparatus 30. The backflow prevention apparatus 30 is disposed at an air outlet of an air moving unit 10B (reference may be made to FIG. 1), so that when a single air moving unit 10B fails, air is prevented, by using a corresponding backflow prevention apparatus 30, from flowing back to the single air moving unit 10B.

More specifically, as shown in FIG. 6, in this embodiment, the backflow prevention apparatus 30 includes multiple rotatable blades 31 that jointly form a shutter-type structure. Under a condition where the air moving units 10B (reference may be made to FIG. 1) normally supply air, the multiple rotatable blades 31 in the backflow prevention apparatus 30 are open because of acting force of airflow, that is, the backflow prevention apparatus 30 is enabled. When a single air moving unit 10B (reference may be made to FIG. 1) fails, because of an impact of a difference between internal pressure and external pressure of the cooling system 1 (reference may be made to FIG. 1), multiple rotatable blades 31 of a backflow prevention apparatus 30 corresponding to the failed air moving unit 10B fall downwards, that is, the backflow prevention apparatus 30 is disabled. In this way, a backflow prevention function of the failed air moving unit 10B is implemented.

Specifically, as shown in FIG. 1, in this embodiment, the air moving unit 10B is preferably a fan, and the multiple air moving units 10B are preferably connected in parallel.

Certainly, a person of ordinary skill in the art may understand that the air moving unit may further be a blower or another air moving device.

Specifically, as shown in FIG. 1, in this embodiment, the fan is preferably a speed-adjustable fan, and when a single fan fails, a same airflow volume can be reached by adjusting a rotational speed of a properly-functioning fan.

### Embodiment 2

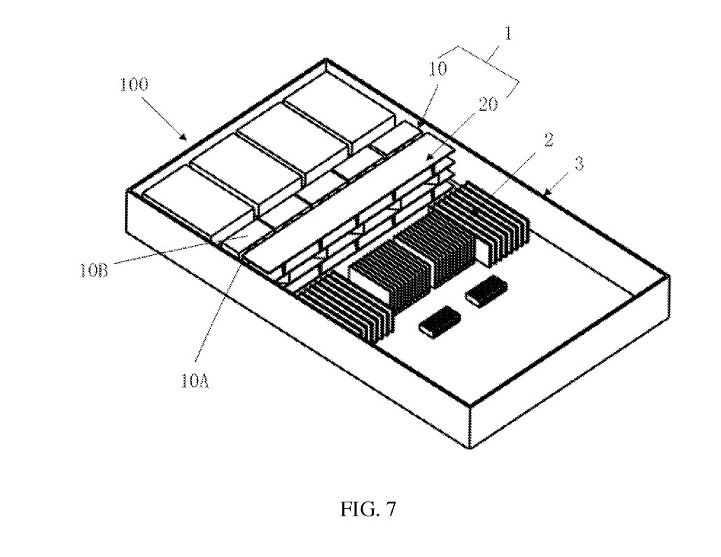

As shown in FIG. 7, an embodiment of the present disclosure further provides an electronic device 100, including an enclosure 3 and an electronic component. The electronic component is disposed inside the enclosure 3, and the electronic component is a heating component 2. The electronic device 100 further includes an air cooling system 1, and the air cooling system 1 is disposed inside the enclosure 3 and performs, by using an air deflecting apparatus 20, layering and deflecting for outgoing air of multiple air moving units 10, so that even heat dissipation airflow is formed at an outlet of the air deflecting apparatus 20, so as to perform heat dissipation for the electronic component. A structure of the cooling system in this embodiment is totally the same as that of the cooling system in Embodiment 1, and therefore details about the cooling system part are not repeatedly described in this embodiment.

The embodiment of the present disclosure includes the foregoing cooling system. An air deflecting apparatus 20 is disposed between an air outlet 10A of multiple air moving units and a heating component 2, and layering and deflecting are performed, by using the air deflecting apparatus 20, for outgoing air of the multiple air moving units 10, so that even heat dissipation airflow is formed at an outlet of the air deflecting apparatus 20, and heat dissipation for the heating component 2 in direct downstream of a faulty air moving unit 10B can still be ensured even in a case in which a single air moving unit 10B fails. Because the foregoing structure is used in the embodiment of the present disclosure, a heat dissipation requirement of the heating component 2 when the multiple air moving units 10 are normally working can be met, and a heat dissipation impact resulting from a failure of a single air moving unit 10B in the multiple air moving units 10 can also be effectively avoided. In comparison with conventional double-layer disposal of multiple air moving units 10, the number of air moving units 10B can be reduced, thereby reducing costs of the air moving units 10B; an overall failure probability of the multiple air moving units 10 can be lowered, thereby reducing maintenance and the number of spare parts; and operating energy consumption of the multiple air moving units 10 and noise can be reduced. Therefore, the electronic device 100 disposed with the cooling system 1 has advantages of a good heat dissipation effect and stable operating.

The sequence numbers of the foregoing embodiments of the present disclosure are merely for description purpose but do not indicate the preference of the embodiments.

The foregoing descriptions are merely exemplary embodiments of the present disclosure but are not intended to limit the present disclosure. Any modification, equivalent replacement, or improvement made within the spirit and principle of the present disclosure shall fall within the protection scope of the present disclosure.

What is claimed is:

1. An air cooling system configured to perform heat dissipation for a heating component, comprising:
multiple air moving units; and
an air deflecting apparatus,
wherein the multiple air moving units are disposed upstream of air flowing through the heating component, and the multiple air moving units are configured to provide air required for dissipating heat for the heating component, and
wherein the air deflecting apparatus is disposed between an air outlet of the multiple air moving units and the heating component, and the air deflecting apparatus is configured to perform vertical layering and deflecting for outgoing air of the multiple air moving units and divide the air into at least two layers, wherein air at each layer is supplied jointly by the multiple air moving units, and air directions of air in at least two adjacent layer spaces are different.

2. The air cooling system according to claim 1, wherein the air deflecting apparatus comprises a horizontal plate and a vertical plate, wherein the horizontal plate is disposed in a horizontal direction, and the horizontal plate is configured to divide the outgoing air of the multiple air moving units into at least two layers, and wherein the vertical plate is vertically disposed in at least two layer spaces divided by the horizontal plate, and the vertical plate is configured to deflect air in a corresponding layer space.

3. The air cooling system according to claim 2, wherein the air deflecting apparatus comprises N horizontal plates and (N−1) vertical plates, the N horizontal plates are triangular plates, the N horizontal plates are disposed in parallel in a vertical direction, all long edges of the triangular plates face air outlets of the multiple air moving units, the (N−1) vertical plates are separately disposed in layer spaces formed by the N horizontal plates, a vertical plate in each layer space is disposed vertically at one short edge of a horizontal plate in the layer space, vertical plates between at least two adjacent layers are disposed in a staggered manner at short edges of a horizontal plate shared by the vertical plates, and N≧2.

4. The air cooling system according to claim 2, wherein the air deflecting apparatus comprises multiple horizontal plates and multiple vertical plates, wherein the multiple horizontal plates are rectangular plates, the multiple horizontal plates are disposed in parallel in a vertical direction, all long edges of the rectangular plates face air outlets of the multiple air moving units, the multiple vertical plates are disposed vertically and regularly in layer spaces formed by the multiple horizontal plates, a vertical plate in each layer space is disposed in a same direction such that same air deflecting is formed in the layer space, and vertical plates in at least two adjacent layer spaces are disposed in a staggered manner such that staggered air deflecting is formed in the at least two adjacent layer spaces.

5. The air cooling system according to claim 2, wherein the air deflecting apparatus comprises an integrated structure.

6. The air cooling system according to claim 2, wherein the air deflecting apparatus comprises a split structure, the air deflecting apparatus comprises multiple air deflecting units, the multiple air deflecting units correspond to the multiple air moving units in a one-to-one manner, the multiple air deflecting units are independent of each other, and the air deflecting units each deflect air for an air moving unit corresponding to the air deflecting units, wherein each air deflecting unit divides, by using a horizontal plate, outgoing air of an air moving unit corresponding to each air deflecting unit into at least two layers, and outgoing air deflecting of adjacent layers is different such that air directions of outgoing air of the adjacent layers are different, wherein deflecting of all air deflecting units at a same layer in the air deflecting apparatus are the same such that air directions of outgoing air of the same layer in the air deflecting apparatus are the same, and wherein deflecting of air deflecting units at adjacent layers in the air deflecting apparatus is different such that air directions of outgoing air of the adjacent layers in the air deflecting apparatus are different.

7. The air cooling system according to claim 1, wherein the air cooling system comprises multiple backflow prevention apparatuses, the multiple air moving units each have a backflow prevention apparatus, and the backflow prevention apparatus is disposed at an air outlet of an air moving unit such that when a single air moving unit fails, air is prevented, by using a corresponding backflow prevention apparatus, from flowing back to the single air moving unit.

8. The air cooling system according to claim 1, wherein the air moving unit is a fan, and the multiple air moving units are connected in parallel.

9. The air cooling system according to claim 8, wherein the fan is a speed-adjustable fan, and when a single fan fails, a same airflow volume can be reached by adjusting a rotational speed of a properly-functioning fan.

10. An electronic device, comprising:
an enclosure; and
an electronic component,
wherein the electronic component is disposed inside the enclosure, the electronic component is a heating component, the electronic device further comprises an air cooling system,
wherein the air cooling system comprises multiple air moving units and an air deflecting apparatus,
wherein the multiple air moving units are disposed upstream of air flowing through the heating component, and the multiple air moving units are configured to provide air required for dissipating heat for the heating component,
wherein the air deflecting apparatus is disposed between an air outlet of the multiple air moving units and the heating component, and the air deflecting apparatus is configured to perform vertical layering and deflecting for outgoing air of the multiple air moving units and divide the air into at least two layers, wherein air at each layer is supplied jointly by the multiple air moving units, and air directions of air in at least two adjacent layer spaces are different, and
wherein the air cooling system is disposed inside the enclosure and performs, by using the air deflecting apparatus, layering and deflecting for outgoing air of the multiple air moving units such that even heat dissipation airflow is formed at an outlet of the air deflecting apparatus to perform heat dissipation for the electronic component.

11. The electronic device according claim 10, wherein the air deflecting apparatus comprises a horizontal plate and a vertical plate, wherein the horizontal plate is disposed in a horizontal direction, and the horizontal plate is configured to divide the outgoing air of the multiple air moving units into at least two layers, and wherein the vertical plate is vertically disposed in at least two layer spaces divided by the horizontal plate, and the vertical plate is configured to deflect air in a corresponding layer space.

12. The electronic device according claim 11, wherein the air deflecting apparatus comprises N horizontal plates and (N−1) vertical plates, the N horizontal plates are triangular plates, the N horizontal plates are disposed in parallel in a vertical direction, all long edges of the triangular plates face air outlets of the multiple air moving units, the (N−1) vertical plates are separately disposed in layer spaces formed by the N horizontal plates, a vertical plate in each layer space is disposed vertically at one short edge of a horizontal plate in the layer space, vertical plates between at least two adjacent layers are disposed in a staggered manner at short edges of a horizontal plate shared by the vertical plates, and N≧2.

13. The electronic device according claim 11, wherein the air deflecting apparatus comprises multiple horizontal plates and multiple vertical plates, the multiple horizontal plates are rectangular plates, the multiple horizontal plates are disposed in parallel in a vertical direction, all long edges of the rectangular plates face air outlets of the multiple air moving units, the multiple vertical plates are disposed vertically and regularly in layer spaces formed by the multiple horizontal plates, a vertical plate in each layer space is disposed in a same direction such that same air deflecting is formed in the layer space, and vertical plates in at least two adjacent layer spaces are disposed in a staggered manner such that staggered air deflecting is formed in the at least two adjacent layer spaces.

14. The electronic device according claim 11, wherein the air deflecting apparatus comprises an integrated structure.

15. The electronic device according claim 11, wherein the air deflecting apparatus comprises a split structure, the air deflecting apparatus comprises multiple air deflecting units, the multiple air deflecting units correspond to the multiple air moving units in a one-to-one manner, the multiple air deflecting units are independent of each other, and the air deflecting units each deflect air for an air moving unit corresponding to the air deflecting units, wherein each air deflecting unit divides, by using a horizontal plate, outgoing air of an air moving unit corresponding to each air deflecting unit into at least two layers, and outgoing air deflecting of adjacent layers is different such that air directions of outgoing air of the adjacent layers are different, and wherein deflecting of all air deflecting units at a same layer in the air deflecting apparatus are the same such that air directions of outgoing air of the same layer in the air deflecting apparatus are the same; and deflecting of air deflecting units at adjacent layers in the air deflecting apparatus is different such that air directions of outgoing air of the adjacent layers in the air deflecting apparatus are different.

16. The electronic device according claim 10, wherein the air cooling system comprises multiple backflow prevention apparatuses, the multiple air moving units each have a backflow prevention apparatus, and the backflow prevention apparatus is disposed at an air outlet of an air moving unit such that when a single air moving unit fails, air is prevented, by using a corresponding backflow prevention apparatus, from flowing back to the single air moving unit.

17. The electronic device according claim 10, wherein the air moving unit is a fan, and the multiple air moving units are connected in parallel.

18. The electronic device according claim 17, wherein the fan is a speed-adjustable fan, and when a single fan fails, a same airflow volume can be reached by adjusting a rotational speed of a properly-functioning fan.
